(19) United States
(12) Patent Application Publication
(10) Pub. No.: US 2008/0157351 A1
(43) Pub. Date: Jul. 3, 2008

(54) SEMICONDUCTOR DEVICE FABRICATING METHOD

(76) Inventor: Jae-Won Han, Gyeongi-do (KR)

Correspondence Address: SHERR & NOURSE, PLLC, 620 HERNDON PARKWAY, SUITE 200, HERNDON, VA, 20170, US

(21) Appl. No.: 11/928,939

(22) Filed: Oct. 30, 2007

(30) Foreign Application Priority Data
Dec. 27, 2006 (KR) 10-2006-0135745

(51) Int. Cl. H01L 21/50; H01L 23/12

(52) U.S. Cl. 257/723; 438/110; 438/113; 257/E23.003; 257/E21.499

(57) ABSTRACT

A semiconductor device may includes a first semiconductor substrate provided on a second semiconductor substrate in a system-in-package arrangement. The first semiconductor substrate may include a plurality of through electrodes formed in first semiconductor substrate. The second semiconductor substrate may include a transistor layer formed over the second semiconductor substrate and a multilayer metal layer formed over the second semiconductor substrate. A plurality of connection electrodes for electrically connecting the first semiconductor substrate to the second semiconductor substrate.

The present application claims priority under 35 U.S.C. 119 and 35 U.S.C. 365 to Korean Patent Application No. 10-2006-0135745 (filed on Dec. 27, 2006), which is hereby incorporated by reference in its entirety.

### BACKGROUND

Aspects of semiconductor technology have focused on integration of semiconductor devices. System-on-chip technology (SoC) has been developed to achieve integration of an analog, RF, CPU, and CMOS sensors on a single chip. The SoC process, however, has disadvantages due to the difficulty in integrating on a single chip various types of semiconductor devices having various design rules.

Accordingly, system-in-package technology (SiP) has been developed to achieve a highly-integrated integrated chip having a system level by integrating various components or ICs in a single package. SiP may require providing a plurality of semiconductor devices in a stacked arrangement within a single package. One scheme for stacking layers using SiP technology is stacking an upper wafer on a lower wafer. However, this scheme results in a reduced yield if there is differences in areas having good dies between the upper and lower wafers. Another scheme for stacking layers using SiP technology requires stacking good chips or dies in a chip level by separating the good dies from the upper and lower wafers. However, this scheme requires high manufacturing costs and is too lengthy.

### SUMMARY

Embodiment relate to a method of fabricating a semiconductor device that enhances overall manufacturing efficiency in providing highly-integrated devices having a system level.

Embodiment relate to a method of fabricating a semiconductor device including at least one of the following steps: forming a plurality of upper devices for SiP on and/or over a first wafer and separating good dies from the wafer; forming a plurality of lower devices for SiP on and/or over a second wafer and selecting good dies from among the lower devices; and stacking the good dies separated from the first wafer on and/or over the good dies formed on and/or over the second wafer, thereby forming a SiP type semiconductor device.

Embodiment relate to a method of fabricating a semiconductor device including at least one of the following steps: forming a plurality of upper devices for SiP on and/or over a first wafer and separating good dies from the wafer; forming a plurality of lower devices for SiP on and/or over a second wafer and selecting good dies from among the lower devices; and stacking the good dies separated from the first wafer on and/or over the good dies formed on and/or over the second wafer, thereby forming a SiP type semiconductor device.

### DRAWINGS

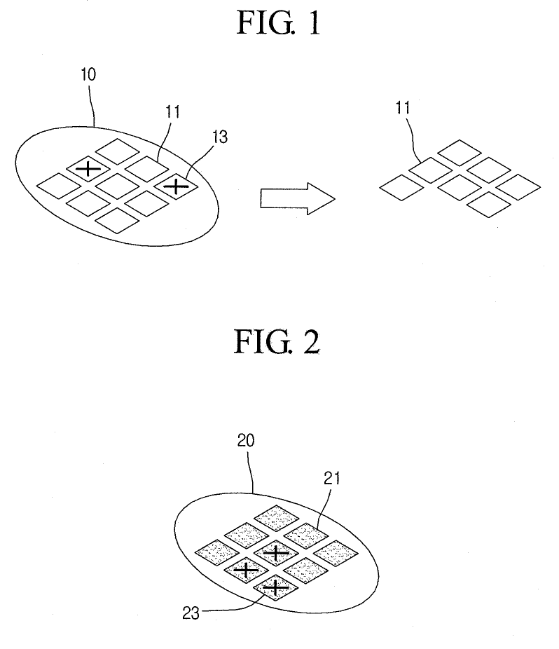

Example FIGS. 1 to 6 illustrate a method of fabricating a semiconductor device, in accordance with embodiments.

### DESCRIPTION

In the description of embodiments, it will be understood that when a layer (or film) is referred to as being ‘on/above’ another layer or substrate, it can be directly on another layer or substrate, or intervening layers may also be present. Further, it will be understood that when a layer is referred to as being ‘below/under’ another layer, it can be directly under another layer, and one or more intervening layers may also be present. In addition, it will also be understood that when a layer is referred to as being ‘between’ two layers, it can be the only layer between the two layers, or one or more intervening layers may also be present. Thus, the meaning thereof must be determined based on the scope of the present invention.

As illustrated in example FIG. 1, embodiments include a method of fabricating a semiconductor device whereby a plurality of upper devices can be formed on and/or over first wafer 10. Then, the upper devices are divided into good dies 11 and bad dies 13 based on the operational state of the upper devices. After that, good dies 11 are separated from the first wafer 10. Good dies 11 can be separated from the first wafer 10 using a sawing process.

When forming the upper devices on and/or over first wafer 10, one or more through electrodes can be formed in first wafer 10 in order to electrically connect the upper devices formed on and/or over first wafer 10 to lower devices formed on and/or over second wafer 20.

As illustrated in example FIG. 2, a plurality of lower devices for SiP can be formed on and/or over second wafer 20 and then the lower devices can be divided into good dies 21 and bad dies 23. At this time, the process for separating good dies 21 from second wafer 20 is not performed. The step of forming the devices on and/or over second wafer 20 can be performed prior to the step of forming the devices on and/or over first wafer 10. Alternatively, the devices can be formed on and/or over first wafer 10 and second wafer 20 simultaneously in difference places.

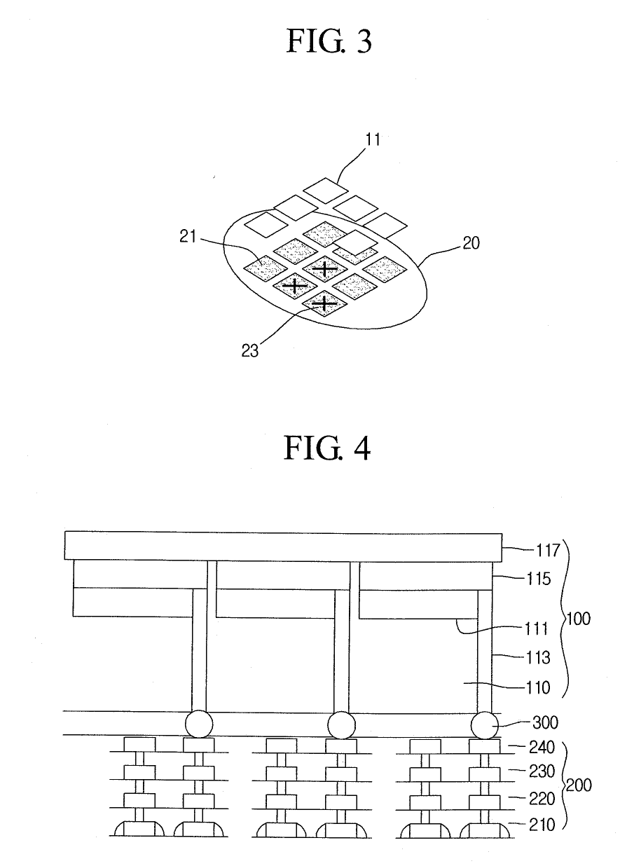

As illustrated in example FIG. 3, good dies 11 separated from first wafer 10 can be stacked on and/or over the good dies 21 of the second wafer 20 in a SiP arrangement. When stacking good dies 11 of first wafer 10 on and/or over good dies 21 of second wafer 20, good dies 11 can be electrically connected to good dies 21 using connection electrodes.

In accordance with embodiments, the stacking process can be performed in a state in which the lower devices are in a wafer level and the upper devices are in a chip level. After stacking the devices in a SiP arrangement, characteristics of the devices can be measured so that the good dies are separated from the wafers through a sawing process. Therefore, chip level good dies can be stacked on and/or over the wafer level good dies in an SiP arrangement in order to enhance the overall yield rate of the semiconductor devices.

As illustrated in example FIG. 4, in accordance with embodiments, an image sensor stacked in a SiP arrangement can include first semiconductor substrate 100, second semiconductor substrate 200 and a plurality of connection electrodes 300. Connection electrodes 300 electrically connect a plurality of photodiode cells 111 formed on and/or over first substrate 100 to a logic circuit formed on and/or over second substrate 200. Connection electrodes 300 can be electrically connected at one end to photodiode cells 111 using a plurality of through electrodes 113 formed in first substrate 100. Connection electrodes 300 can be electrically connected at another end to an uppermost electrode which is third metal layer 240 that forms the logic circuit.

In accordance with embodiments, the plurality of photodiode cells 111, the plurality of through electrodes 113 and a plurality of color filters 115 can be formed on and/or over first substrate 100. First, photodiode cells 111 can be formed on and/or over an upper portion of semiconductor substrate 110. Then, through electrodes 113 can be formed to pass through semiconductor substrate 110 so as to be electrically connected to photodiode cells 111. Through electrode 113 can be obtained by sequentially performing a patterning process, an etching process, and a metal forming process relative to semiconductor substrate 110. Then, color filters 115 can be formed on and/or over photodiode cells 111 and protective layer 117 can be formed on and/or over color filters 115.

Through electrode 113 may be composed of at least one material selected from the group consisting of W, Cu, Al, Ag, and Au. Through electrode 113 can be deposited using CVD, PVD, evaporation, or ECP. In addition, at least one metal of TaN, Ta, TiN, Ti, and TiSiN can be used as a barrier metal of through electrode 113. The barrier metal can be formed using CVD, PVD, or ALD.

In accordance with embodiments, second semiconductor substrate 200 can include a logic circuit for processing signals, the logic circuit including transistor layer 210, first metal layer 220, second metal layer 230 and third metal layer 240 formed thereon and/or thereover. While a multilayer metal layer composed of three layers is illustrated, the total number of metal layers may vary depending on the design of the semiconductor device.

A plurality of transistors can be formed in transistor layer 210 in correspondence with photodiode cells 111 formed on and/or over first semiconductor substrate 100. The transistors can be aligned in an area corresponding to the photodiode cell area and the number of transistors may vary depending on applications thereof. In accordance with embodiments, the photodiode cell area can be arranged in a larger than typical arrangement so the number of transistors may not be limited. Therefore, a large number of transistors can be formed in transistor layer 210 to enhance the characteristics of the image sensor. Moreover, it is not necessary to use a fine circuit forming process to provide the logic circuit.

As illustrated in example FIG. 4, it is not necessary to provide the logic circuit on the photodiode cells 111. Particularly, photodiode cells 111 can be directly exposed to external light without interfering with obstacles, so the image sensor in accordance with embodiments may not require an additional micro-lens.

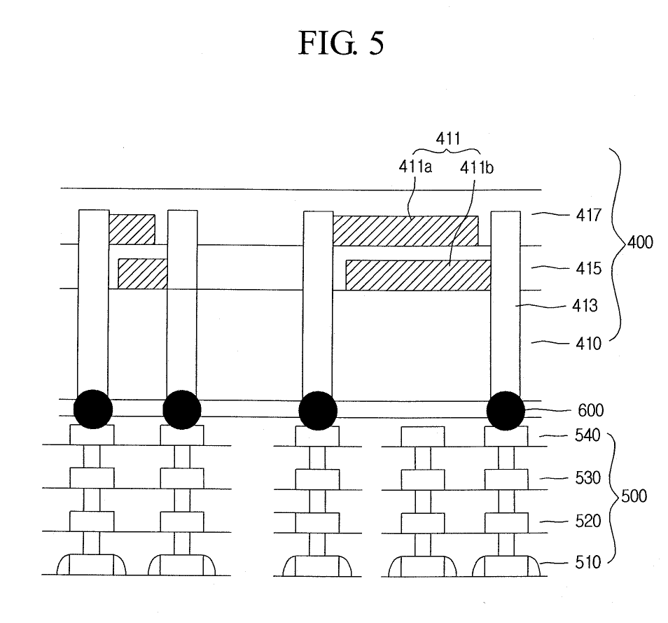

As illustrated in example FIG. 5, in accordance with embodiments, a semiconductor device having a capacitor stacked in a SiP arrangement can include first semiconductor substrate 400, second semiconductor substrate 500 and a plurality of connection electrodes 600. Connection electrodes 600 can electrically connect at a first end capacitor cells 411 formed on and/or over first substrate 400 to a logic circuit formed on and/or over second substrate 500. Each connection electrode 600 can be electrically connected to capacitor cells 411 using through electrodes 413 formed on and/or over first substrate 400. Connection electrodes 600 can be connected at a second end to an uppermost electrode including third metal layer 540 forming the logic circuit of second semiconductor substrate 500.

In accordance with embodiments, capacitor cells 411 formed on and/or over first substrate 400 may include upper electrode 411a and lower electrode 411b that can be electrically connected to through electrode 413. The alignment position of through electrode 413 can be variously changed in accordance with requirements.

Lower electrode 411b insulating layer 415, and upper electrode 411a can be formed on and/or over semiconductor substrate 410. An additional insulating layer can be interposed between semiconductor substrate 410 and lower electrode 411b.

In addition, through electrodes 413 can be formed so as to pass through semiconductor substrate 410 and be electrically connected to capacitor cells 411. Through electrode 413 can be formed by sequentially performing a patterning process, an etching process, a metal forming process, and a CMP process relative to semiconductor substrate 410. Then, protective layer 417 is formed on the capacitor cell 411.

Upper electrode 411a, lower electrode 411b and through electrode 413 may be composed of at least one material selected from the group consisting of W, Cu, Al, Ag, and Au. Capacitor cell 411 and through electrode 413 can be deposited using CVD, PVD, evaporation, or ECP. In addition, TaN, Ta, TiN, Ti, or TiSiN can be used as a barrier metal of through electrode 113. The barrier metal can be formed using CVD, PVD, or ALD.

In accordance with embodiments, second semiconductor substrate 500 may include a logic circuit for processing signals including transistor layer 510, first metal layer 520, second metal layer 530 and third metal layer 540. While a multilayer metal layer composed of three layers is illustrated, the total number of metal layers may vary depending on the design of the semiconductor device.

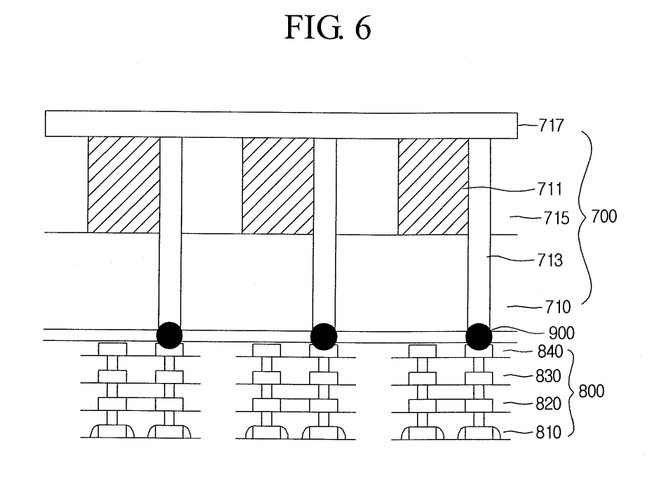

As illustrated in example FIG. 6, in accordance with embodiments, a semiconductor device having an inductor may include first substrate 700, second substrate 800 and connection electrodes 900. Connection electrodes 900 can be provided to electrically connect inductor cells 711 formed on and/or over first substrate 700 to an RF device circuit formed on and/or over second substrate 800. Connection electrodes 900 can be electrically connected to inductor cells 711 at one end using through electrodes 713 formed in first substrate 700. Connection electrodes 900 can be electrically connected at a second end to an uppermost electrode that includes third metal layer 840 that forms the RF device circuit on second semiconductor substrate 800.

In accordance with embodiments, first substrate 700 may include inductor cells 711, through electrodes and insulating layer 715 formed thereon and/or thereover. A patterning process may then be performed to form the inductor. After performing an etching process, an inductor barrier metal may be deposited and the inductor metal layer filled. Then, a CMP process may be performed relative to the resultant structure, thereby forming inductor cells 711.

Through electrodes 713 can then be formed to pass through first semiconductor substrate 710 and electrically connected to inductor cells 711. Through electrodes 713 can be obtained by sequentially performing a patterning process, an etching process, a metal forming process, and a CMP process relative to semiconductor substrate 710. Then, protective layer 717 can be formed on and/or over inductor cells 711.

Inductor cells 711 and through electrodes 713 may include at least one material selected from the group consisting of W, Cu, Al, Ag, and Au. Inductor cells 711 and through electrodes 713 can be deposited using CVD, PVD, evaporation, or ECP. In addition, TaN, Ta, TiN, Ti, or TiSiN can be used as a barrier metal of inductor cells 711 and through electrodes 713. The barrier metal can be formed using CVD, PVD, or ALD.

In accordance with embodiments, second semiconductor substrate 800 may include an RF device for processing signals including transistor layer 810, first metal layer 820, second metal layer 830 and third metal layer 840. While a multilayer metal layer composed of three layers is illustrated, the total number of metal layers may vary depending on the design of the semiconductor device.

In accordance with embodiments, a method of fabricating a semiconductor device can be provided in a simplified manner in order to achieve enhanced manufacturing efficiency and a highly-integrated device having a system level.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a plurality of upper devices on a first wafer;
classifying the plurality of upper devices into good upper devices and bad upper devices based on the operational state of the upper devices;
separating the good upper devices from the first wafer;
forming a plurality of lower devices on a second wafer, wherein the plurality of lower devices include good lower devices and bad lower devices;
classifying the plurality of lower devices into good lower devices and bad lower devices;
selecting the good lower devices from among the lower devices; and
forming a plurality of system-in-package type semiconductor devices by stacking the good upper devices separated from the first wafer on the good lower devices provided on the second wafer.

2. The method of claim 1, further comprising forming a plurality of through electrodes in the first wafer to electrically connect the good upper devices formed on the first wafer to the good lower devices formed on the second wafer.

3. The method of claim 1, wherein the good upper devices are separated from the first wafer using a sawing process.

4. The method of claim 1, wherein the good upper devices separated from the first wafer are electrically connected to the good lower devices formed on the second wafer using connection electrodes.

5. The method of claim 1, further comprising performing quality inspection with respect to the system-in-package type semiconductor devices and separating the system-in-package type semiconductor devices inspected to have high quality in a device unit.

6. The method of claim 5, wherein each system-in-package type semiconductor device includes an image sensor.

7. The method of claim 5, wherein each system-in-package type semiconductor device includes a capacitor.

8. The method of claim 5, wherein each system-in-package type semiconductor device includes an inductor.

9. The method of claim 2, wherein the plurality of through electrodes is composed of at least one material selected from the group consisting of W, Cu, Al, Ag, and Au.

10. A method comprising:
forming a plurality of upper devices including a plurality of photodiode cells and a plurality of color filters on a first wafer;
separating good dies from the first wafer;
forming a plurality of lower devices including a logic circuit on a second wafer and selecting good dies from among the plurality of lower devices; and
forming a plurality of system-in-package type semiconductor devices by stacking the good dies separated from the first wafer on the good dies provided on the second wafer.

11. The method of claim 10, further comprising forming a plurality of through electrodes in the first wafer to electrically connect the upper devices formed on the first wafer to the lower devices formed on the second wafer.

12. The method of claim 10, wherein the good dies are separated from the first wafer using a sawing process.

13. The method of claim 10, further comprising a plurality of through connection electrodes to electrically connect the good dies separated from the first wafer to the good dies formed on the second wafer.

14. The method of claim 10, further comprising performing quality inspection with respect to the system-in-package type semiconductor devices and separating the system-in-package type semiconductor devices inspected to have high quality in a device unit.

15. The method of claim 11, wherein the plurality of through electrodes is composed of at least one material selected from the group consisting of W, Cu, Al, Ag, and Au.

16. An apparatus comprising:
a first semiconductor substrate including a plurality of through electrodes formed in first semiconductor substrate;
a second semiconductor substrate including a transistor layer formed over the second semiconductor substrate and a multilayer metal layer formed over the second semiconductor substrate;
a plurality of connection electrodes each electrically connected at one end to a respective through electrode and at another end to the multilayer metal layer,
wherein the first semiconductor substrate is provided on the second semiconductor substrate in a system-in-package arrangement.

17. The apparatus of claim 16, wherein the first semiconductor device includes a plurality of color filters formed over the first semiconductor substrate, a plurality of photodiodes formed over the first semiconductor substrate, and a protective layer formed over the plurality of color filters.

18. The apparatus of claim 16, wherein the first semiconductor device includes at least one insulating layer formed over the first semiconductor substrate, a plurality of capacitors having an upper electrode and a lower electrode formed over the first semiconductor substrate and a protective layer formed over the plurality of capacitors.

19. The apparatus of claim 16, wherein the first semiconductor device includes at least one insulating layer formed over the first semiconductor substrate, a plurality of inductors formed over the first semiconductor substrate and a protective layer formed over the plurality of capacitors.

20. The apparatus of claim 16, wherein the second semiconductor device includes one of a logic circuit and a RF device circuit.
